(19) United States
(12) Patent Application Publication
(10) Pub. No.: US 2018/0350663 A1
(43) Pub. Date: Dec. 6, 2018

(54) METHOD OF FORMING SEMICONDUCTOR DEVICE

(71) Applicant: UNITED MICROELECTRONICS CORP., Hsin-Chu City (TW)

(72) Inventors: WEI ZHANG, Singapore (SG); SUN HOI GOH, Singapore (SG); Zhao Yang Ma, Singapore (SG)

(21) Appl. No.: 15/610,633

(22) Filed: Jun. 1, 2017

(51) Int. Cl. H01L 21/768; H01L 21/02

(52) U.S. Cl. CPC H01L 21/76814; H01L 21/76811; H01L 21/76877; H01L 21/02063; H01L 21/7684; H01L 21/76826; H01L 21/76828; H01L 21/76843

(57) ABSTRACT

The present invention provides a method of forming a semiconductor device including the following steps. First of all, a dielectric layer is formed, and a helium plasma treatment is performed on the dielectric layer. Next, an acid cleaning process is performed on a surface of the dielectric layer after performing the helium plasma treatment. Then, an alkaline brushing process is performed on the surface.

### BACKGROUND OF THE INVENTION

### 1. Field of the Invention

The present invention relates to a method of forming a semiconductor device, and more particularly to a method of forming a dual damascene structure having a low-k dielectric layer.

### 2. Description of the Prior Art

Damascene interconnect processes incorporated with copper are known in the art, which are also referred to as “copper damascene processes” in the semiconductor industry. Generally, the copper damascene processes are categorized into single damascene process and dual damascene process. Because the dual damascene has advantages of simplified processes, lower contact resistance between wires and plugs, and improved reliance, it is widely applied in a damascene interconnect technique. In addition, for reducing resistance and parasitic capacitance of the multi-level interconnect and improving speed of signal transmission, the dual damascene interconnect in the state-of-the-art is fabricated by filling a trench or via patterns located in a dielectric layer that includes a low-K material with copper and performing a planarization process to obtain a metal interconnect.

In conventional damascene processes, defects generated from prior processes may therefore affect the quality of the product in the subsequent metallization process. Consequently, how to improve the possible defects generated during the damascene processes is still an important issue in the field.

### SUMMARY OF THE INVENTION

It is one of the primary objectives of the present invention to provide a method of forming a semiconductor device, in which a cleaning process is additionally performed on entire surfaces of a dielectric layer before a chemical mechanical polishing (CMP) process, thereto effectively remove defects on the dielectric layer without causing any side effects.

To achieve the purpose described above, the present invention provides a method of forming a semiconductor device which includes the following steps. First of all, a dielectric layer is formed, and a helium plasma treatment is performed on the dielectric layer. Next, an acid cleaning process is performed on a surface of the dielectric layer after performing the helium plasma treatment. Then, an alkaline brushing process is performed on the surface.

Overall, the present invention provides an effective method of forming the dual damascene structure with better yield and quality, in which, at least two cleaning processes are performed, with the first cleaning process being performed before the CMP process, and with the second cleaning process being performed after the CMP process. That is, the possible defects generated from the deposition of the dielectric layer may be sufficient removed through the first cleaning process without leading to any side effects, and the wafer products obtained in the present invention may therefore have better yield and quality.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 7 are schematic diagrams illustrating a method of forming a semiconductor device according to a first/second embodiment of the present invention, in which:

FIG. 1 illustrates a cross-sectional view of a semiconductor device after forming a dielectric layer;

FIG. 2 illustrates a cross-sectional view of a semiconductor device after performing a treatment process;

FIG. 3 illustrates a cross-sectional view of a semiconductor device after forming a via opening;

FIG. 4 illustrates a cross-sectional view of a semiconductor device after forming a trench opening;

FIG. 5 illustrates a cross-sectional view of a semiconductor device after performing a planarization process;

FIG. 6 illustrates a cross-sectional view of a semiconductor device after performing a cleaning process after the planarization process; and

FIG. 7 illustrates a flow chart of the cleaning process of the present invention.

FIG. 8 is a schematic diagram illustrating surface defects of a semiconductor device according to a second embodiment of the present invention.

FIG. 9 to FIG. 10 are schematic diagrams illustrating a method of forming a semiconductor device according to a third embodiment of the present invention, in which:

FIG. 9 illustrates a cross-sectional view of a semiconductor device after performing another cleaning process; and

FIG. 10 illustrates a flow chart of the another cleaning process of the present invention.

### DETAILED DESCRIPTION

To provide a better understanding of the presented invention, preferred embodiments will be described in detail. The preferred embodiments of the present invention are illustrated in the accompanying drawings with numbered elements.

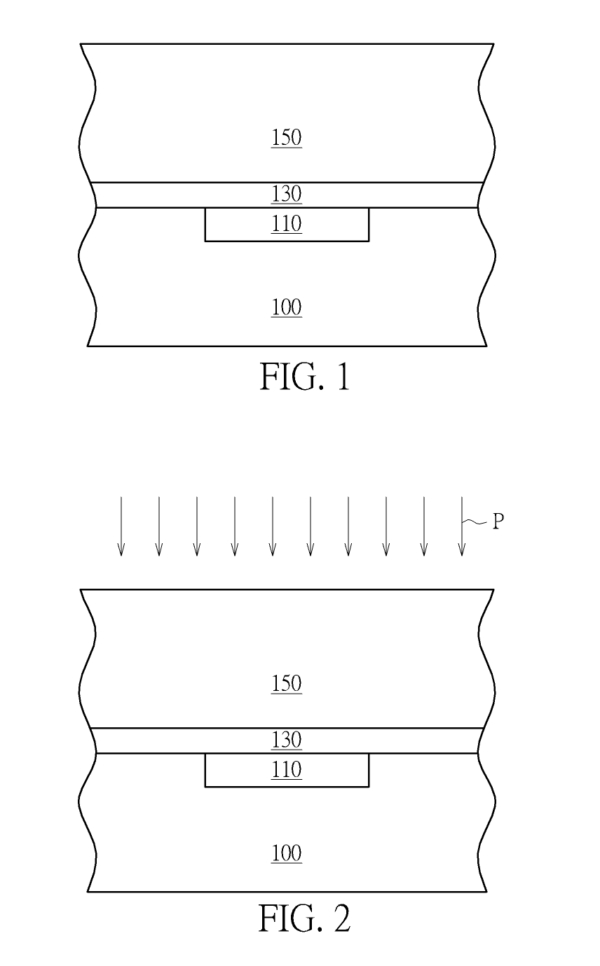

Please refer to FIG. 1 to FIG. 7, which are schematic diagrams illustrating a forming process of a semiconductor device according to the first embodiment of the present invention. First of all, a substrate layer 100 is provided and a conductive layer 110 is formed either in the substrate layer 100 as shown in FIG. 1 or on the substrate layer 100 (not shown in the drawings). In the present embodiment, the substrate layer 100 is a dielectric layer for example including silicon oxide (SiO₂) disposed on a semiconductor substrate (not shown in the drawings) such as a silicon substrate, a silicon germanium substrate or a silicon-on-insulator (SOI) substrate, and the conductive layer 110 is a via plug or a metal line formed in the substrate layer 100 (namely the dielectric layer), over the semiconductor substrate. However, in other embodiments, the substrate layer 100 may be the semiconductor substrate itself, and the conductive layer may be a gate (not shown in the drawings) or a contact plug (not shown in the drawings) disposed thereon, or a doped region (not shown in the drawings) disposed therein, but is not limited thereto.

Then, a passivation layer 130 and a dielectric layer 150 are formed sequentially on the conductive layer 110 and the substrate layer 100, for example through a deposition process. In the present embodiment, the passivation layer 130 and the dielectric layer 150 are preferable include dielectric materials with different etching selectivity. For example, the passivation layer 130 includes silicon oxynitride (SiON) or silicon carbonitride (SiCN), and the dielectric layer 150 includes a low-k dielectric material such as HSQ (hydrogen silsesquioxane, K=2.8), MSQ (methyl silsesquioxane, K=2.7), HOSP (K=2.5), H-PSSQ (hydrio polysilsesquioxane), M-PSSQ (methyl polysilsesquioxane), P-PSSQ (phenyl polysilsesquioxane) or porous sol-gel, but is not limited thereto. In another embodiment, the dielectric layer 150 may include a multilayer structure for example including a middle stop layer sandwiched between two low-k dielectric layers, but is not limited thereto.

Next, a treatment process P is performed on the dielectric layer 150 as shown in FIG. 2, for increasing the tensile and the hydrophilicity of the dielectric layer 150. For example, a curing process and/or a helium plasma treatment are performed on the dielectric layer 150 after the deposition process, and depending on the demand of the product, the aforementioned two treatments may be conducted interchangeably or individually without one another. In the present embodiment, the curing process and the helium plasma treatment are sequentially performed on the dielectric layer 150, with the helium plasma treatment including a helium flow rate in a range between 100 and 10,000 sccm, a power in a range between 50 and 5000 W, and a pressure in a range between 0.1 mTorr and 10 Torr for example, but is not limited thereto.

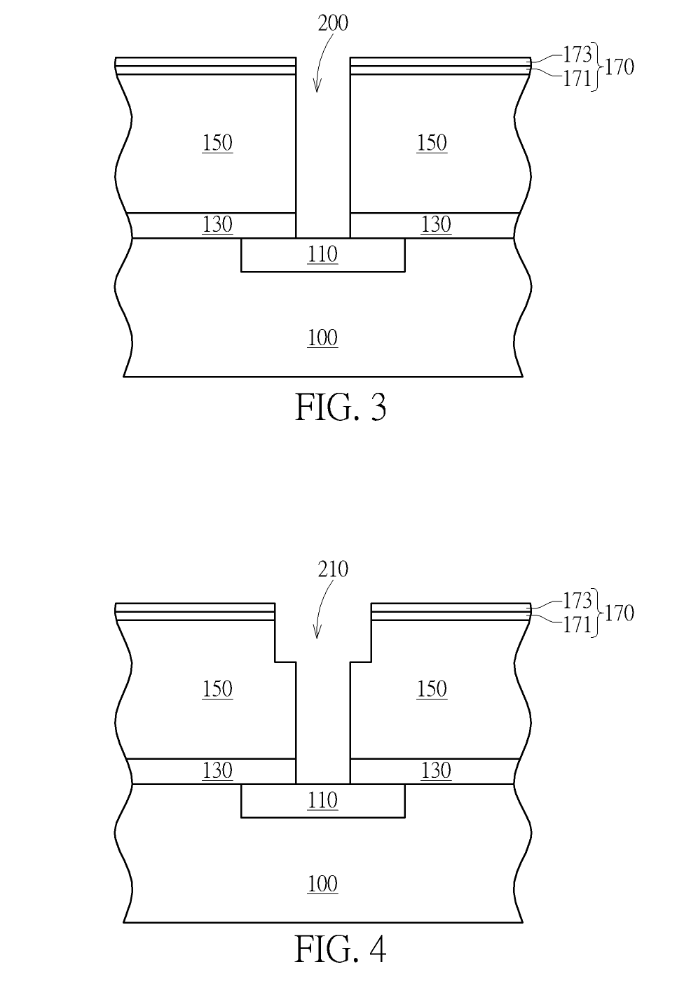

After the treatment process P, a dual damascene structure 300 is formed in the dielectric layer 150, for example through a via first process. In the present embodiment, a mask layer 170 for example including a first mask layer 171 such as including silicon oxynitride, and a second mask layer 173 such as including titanium nitride, and a photoresist layer (not shown in the drawings) are sequentially formed on the dielectric layer 150. Then, a portion of the dielectric layer 150 and a portion of the passivation layer 130 are sequentially removed to form a via opening 200 as shown in FIG. 3 within the dielectric layer 150 and the passivation layer 130. Next, another portion of the dielectric layer 150 is further removed to forma trench opening 210 as shown FIG. 4 within the dielectric layer 150 only. It is noted that, the formation of the trench opening 210 is not limited to the aforementioned process, in the embodiment of having the multilayer dielectric layer (not shown in the drawings), the trench opening 210 may be formed by using the middle stop layer as an etch stop layer, and the trench opening may therefore be formed within the top low-k dielectric layer and the middle stop layer.

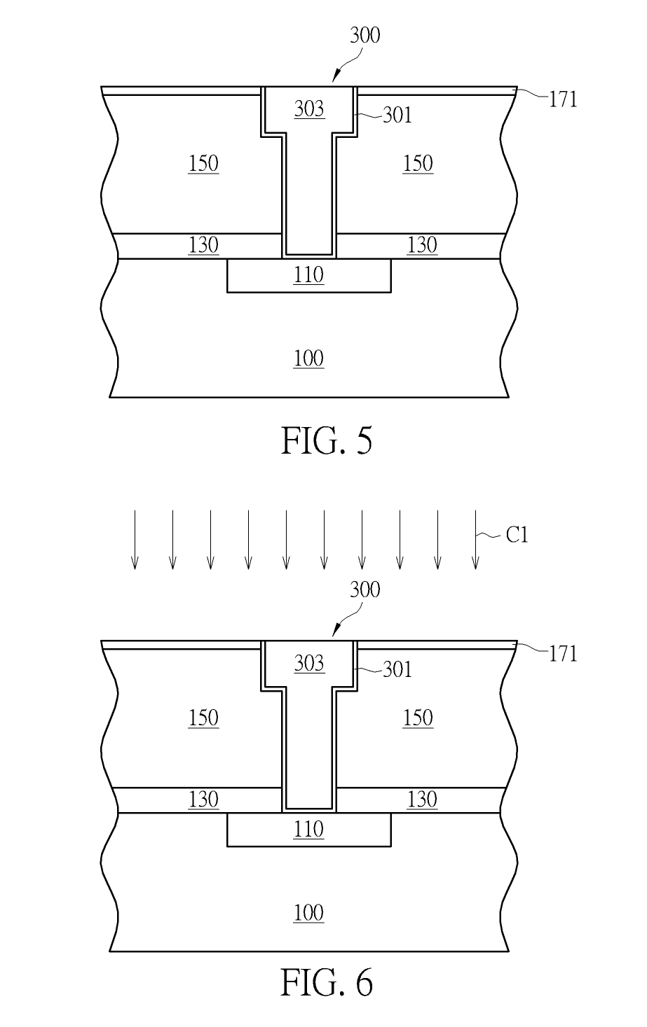

Following these, a barrier layer 301 is formed on surfaces of the via opening 200 and the trench opening 210, and a conductive layer 303 is then formed to filled the via opening 200 and the trench opening 210, thereto form the dual damascene structure 300 as shown in FIG. 5. In the present embodiment, the formation of the barrier layer 301 and the conductive layer 303 is accomplished by sequentially depositing a barrier material layer (not shown in the drawings) such as including Ti/TiN or Ta/TaN and a conductive material layer (not shown in the drawings) such as including copper (Cu) or other low resistant metals, and performing a planarization process such as a chemical mechanical polishing (CMP) process, to remove the barrier material layer and the conductive material layer outside the via opening 200 and the trench opening 210, as well as the second mask layer 173.

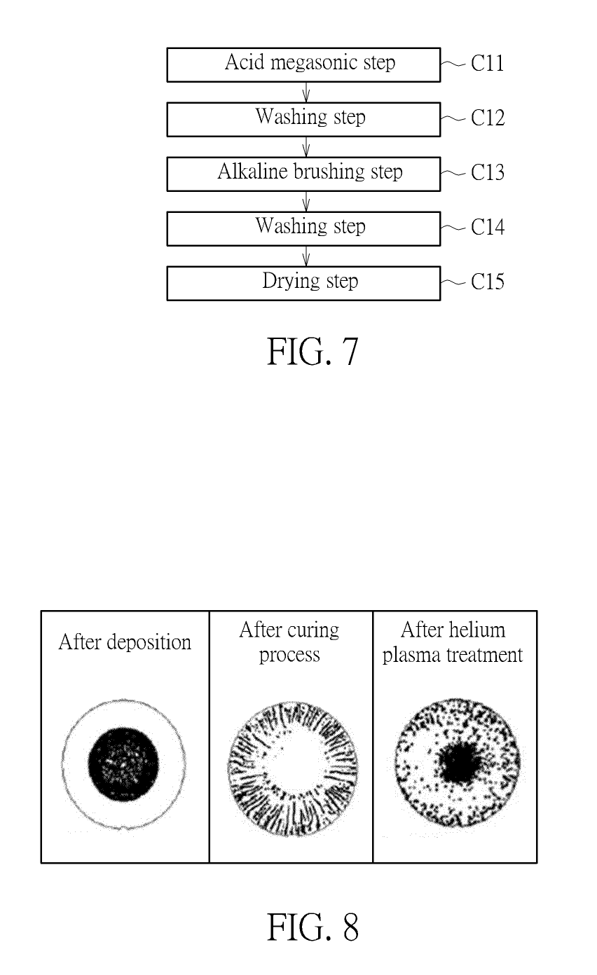

After the CMP process, a cleaning process C1 is performed to remove residue particles and slurry from the wafer surfaces. In the present embodiment, the cleaning process C1 preferably includes a multistep process, for efficiently cleaning the wafer surfaces. For example, as shown in FIG. 7, a first cleaning process C11, by cleaning the wafer surfaces with megasonic in an acid circumstance, such as in 10%-30% citric acid and/or oxalic acid, is firstly performed, followed by performing a first washing process C12, by washing the wafer surfaces with deionized water. Then, a second cleaning process C13, by cleaning the wafer surface with brushing in an alkaline circumstance, such as ESC794 available in ATMI or tetramethylammonium hydroxide (TMAH), is performed, followed by performing a second washing process C14, by washing the wafer surfaces again with deionized water. Finally, a third cleaning process C15 is performed, by drying the wafer surface with isopropyl alcohol (IPA), but is not limited thereto.

Thus, the forming process of a semiconductor device according to the first embodiment is accomplished. According to the present embodiment, only a post-CMP cleaning process C1 is performed after the formation of the dual damascene structure 300. In this way, the present invention is able to obtain the dual damascene structure 300 in a fast and convenient process. However, in some situation, defects may occur while depositing the dielectric layer 150, and those defects may not be removed by the post-CMP cleaning process C1. At this time, a rework process or a further CMP process may be required to improve the defects; otherwise the yield of the wafer products will be reduced thereby.

Please further refers to FIG. 1 to FIG. 7, which are schematic diagrams illustrating a forming process of a semiconductor device according to the second embodiment of the present invention. The formal steps in the present embodiment are similar to those in the first embodiment as shown in FIG. 1, including forming the substrate layer 100, the conductive layer 110, the passivation layer 130 and the dielectric layer 150. The differences between the present embodiment and the aforementioned first embodiment are that, a scrubbing process (not shown in the drawings) is performed on the exposed surface of the dielectric layer 150, either before the treatment process P or after the treatment process P, to remove possible defects on the dielectric layer 150.

Then, the formation of the dual damascene structure 300, and the cleaning process C1 as shown in FIGS. 3-7 of the aforementioned first embodiment are sequentially performed. In the present embodiment, the scrubbing process is performed before the dielectric layer 150 is etched and the CMP process is performed, for removing possible defects from the exposed surface of the dielectric layer 150. In this way, the defects generated from the deposition process may no longer affect the yield of the wafer products. However, although removing the defects, the scrubbing process may further lead to side effects on the exposed surface of the dielectric layer 150, as shown in FIG. 8. Whatever the scrubbing process is performed before the treatment process P (as shown at the left side of FIG. 8), after the curing process (as shown at the middle of FIG. 8), or after the helium process (as shown at the right side of FIG. 8), it all lead to serious side effects on the exposed surfaces. That is, a rework process may still be required in the present embodiment, and the yield of the wafer is still affected thereby.

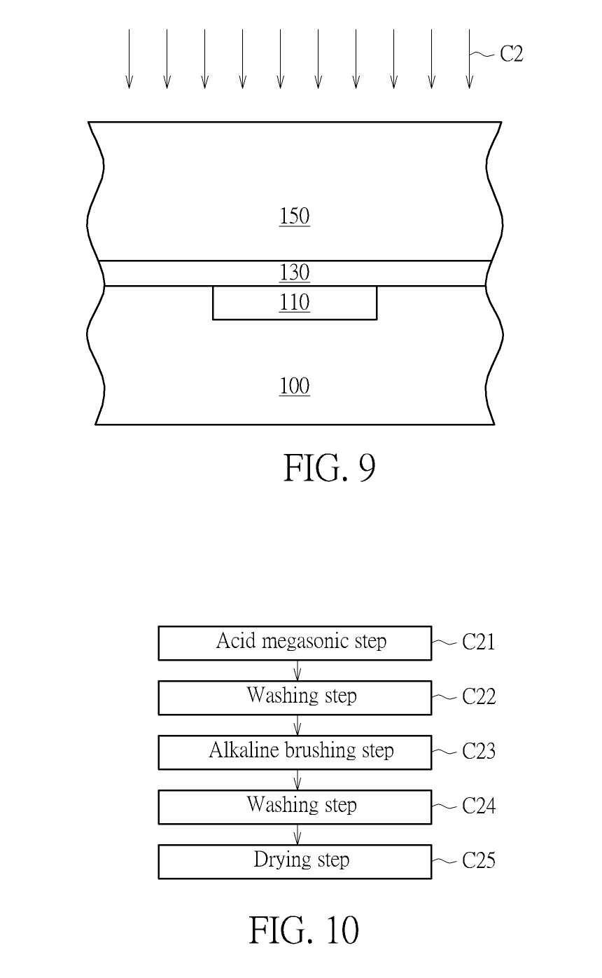

Please refers to FIGS. 1-7 and FIGS. 9-10, which are schematic diagrams illustrating a forming process of a semiconductor device according to the third embodiment of the present invention. The formal steps in the present embodiment are similar to those in the first embodiment as shown in FIGS. 1-2, including forming the substrate layer 100, the conductive layer 110, the passivation layer 130 and the dielectric layer 150, and performing the treatment process P on the dielectric layer 150. The differences between the present embodiment and the aforementioned first embodiment are that, a cleaning process C2 as shown in FIG. 9 is additionally performed on entire exposed surface of the dielectric layer 150, before the formation of the dual damascene structure 300, and after the treatment process P, for removing possible defects on the dielectric layer 150 without leading to any side effects.

Preferably, the cleaning process C2 is performed after the helium plasma treatment because the surfaces of the dielectric layer 150 become more tensile and hydrophilic after the helium plasma treatment. In the present embodiment, the cleaning process C2 preferably includes a multistep process, for efficiently removing the defects on the dielectric layer 150. For example, as shown in FIG. 10, a first cleaning process C21, by cleaning the exposed surfaces of the dielectric layer 150 with megasonic in an acid circumstance, such as in 10%-30% citric acid and/or oxalic acid, is firstly performed, followed by performing a first washing process C22, by washing the exposed surfaces of the dielectric layer 150 with deionized water. Then, a second cleaning process C23, by cleaning the exposed surfaces of the dielectric layer 150 with brushing in an alkaline circumstance, such as ESC794 available in ATMI or TMAH, is performed, followed by performing a second washing process C24, by washing the exposed surfaces of the dielectric layer 150 again with deionized water. Finally, a third cleaning process C25 is performed, by drying the exposed surfaces of the dielectric layer 150 with isopropyl alcohol (IPA), but is not limited thereto.

Then, the formation of the dual damascene structure 300, and the cleaning process C1 as shown in FIGS. 3-7 of the aforementioned first embodiment are sequentially performed. In the present embodiment, the additional cleaning process C2 is further performed before the formation of the dual damascene structure 300, for removing possible defects on the exposed surface of the dielectric layer 150. In other words, the method of the present embodiment performs two cleaning processes, with the first cleaning process C2 being performed before the dielectric layer 150 is etched, the barrier material layer and the conductive material layer are formed, and the CMP process is performed, and with the second cleaning process C1 being performed after the dielectric layer 150 is etched, the barrier material layer and the conductive material layer are formed, and the CMP process is performed. In this way, the present invention is able to obtain the wafer products free from defects and side effects.

It is noteworthy that, since the exposed surface of the dielectric layer 150 may be more tensile and hydrophilic after the helium plasma treatment, defects such as residue particles or slurry on the exposed surface of the dielectric layer 150 will easily be removed by the acid megasonic process and the alkaline brushing process, thereto effectively remove the defects without any side effects. That is, the method of the present embodiment is able to gain wafer products in better yield and quality.

Overall, the present invention provides an effective method of forming the dual damascene structure with better yield and quality, in which, the scrubbing process is avoid to be used on the exposed surface of the dielectric layer for removing defects. According to the present invention, a cleaning process, such as a multistep cleaning process including an acid megasonic process, an alkaline brushing process and a drying process, is performed before the etching of the dielectric layer and the CMP process, to remove such defects. That is, the possible defects generated from the deposition of the dielectric layer may be sufficient removed without leading to any side effects. Also, after the dual damascene structure is formed, another cleaning process, such as a multistep cleaning process including an acid megasonic process, an alkaline brushing process and a drying process, is further performed to clean the wafer surface. Thus, the wafer products obtained in the present invention may therefore have better yield and quality.

Also, it is well known by one skilled in the arts, although the present forming method is exemplified by performing a single time of the cleaning process before the CMP process within the formal embodiment, the forming method of the present invention is not limited thereto. In another embodiment, two or more than two times of the cleaning process may be performed before the CMP process, for example by repeated performing the acid megasonic process, the alkaline brushing process and the drying process on the entire exposed surfaces of the dielectric layer, to remove defects without leading to any side effects. Otherwise, other cleaning processes, such as SC1 or SC2 cleaning process may also be used after the helium plasma treatment to clean such defects on the dielectric layer.

Those skilled in the art will readily observe that numerous modifications and alterations of the device and method may be made while retaining the teachings of the invention. Accordingly, the above disclosure should be construed as limited only by the metes and bounds of the appended claims.

1. A method of forming semiconductor device, comprising:
forming an unetched dielectric layer;
performing a helium plasma treatment on the unetched dielectric layer;
performing an acid cleaning process on a surface of the unetched dielectric layer after the helium plasma treatment;
performing an alkaline brushing process on the surface; and
after the alkaline brushing process and the acid cleaning process, performing a deposition process and a chemical mechanical polishing process to form a dual damascene structure in the unetched dielectric layer.

2. The method of forming the semiconductor device according to claim 1, further comprising:
performing a cleaning process after forming the dual damascene structure.

3. The method of forming the semiconductor device according to claim 2, wherein the forming of the dual damascene structure comprises:
removing a portion of the unetched dielectric layer to form an opening in the dielectric layer; and
performing the deposition process and the chemical mechanical polishing process to form a conductive material layer to fill the opening.

4. The method of forming the semiconductor device according to claim 1, further comprising performing a washing process between the acid cleaning process and the alkaline brushing process.

5. The method of forming the semiconductor device according to claim 1, wherein the acid cleaning process comprises cleaning the surface with megasonic.

6. The method of forming the semiconductor device according to claim 1, wherein the acid cleaning process comprises cleaning the surface in 10%-30% citric acid and/or oxalic acid.

7. The method of forming the semiconductor device according to claim 1, further comprising:
performing a curing process on the unetched dielectric layer before the helium plasma treatment.

8. The method of forming the semiconductor device according to claim 1, further comprising:
performing a drying process after the alkaline brushing process.

9. The method of forming the semiconductor device according to claim 1, wherein after the alkaline cleaning process, further comprises:
repeated performing the acid cleaning process and the alkaline cleaning process on the surface.

10. The method of forming the semiconductor device according to claim 1, wherein the surface of the unetched dielectric layer comprises increased hydrophilicity after performing the helium plasma treatment.

11. The method of forming the semiconductor device according to claim 1, wherein the unetched dielectric layer comprises a low-k dielectric layer.
